(19) United States
(12) Patent Application Publication
(10) Pub. No.: US 2022/0328618 A1
(43) Pub. Date: Oct. 13, 2022

(54) SEMICONDUCTOR POWER DEVICE

(71) Applicant: SUZHOU ORIENTAL SEMICONDUCTOR CO., LTD., Jiangsu (CN)

(72) Inventors: Yi GONG, Jiangsu (CN); Wei LIU, Jiangsu (CN); Lei LIU, Jiangsu (CN); Yuanlin YUAN, Jiangsu (CN)

(21) Appl. No.: 17/257,125

(22) PCT Filed: Nov. 25, 2019
(86) PCT No.: PCT/CN2019/120486

§ 371 Date: Dec. 30, 2020

(30) Foreign Application Priority Data
Sep. 3, 2019 (CN) 201910829144.0

(51) Int. Cl. H01L 29/06; H01L 29/10; H01L 29/40; H01L 29/78

(52) U.S. Cl. CPC H01L 29/0634; H01L 29/1095; H01L 29/407; H01L 29/7813

(57) ABSTRACT

Provided is a semiconductor power device, including an n-type drain region and an n-type epitaxial layer located upon the n-type drain region. The n-type epitaxial layer includes at least two first p-type body regions, where an n-type source region is disposed in a respective one of the at least two first p-type body regions; a p-type columnar doped region located below the respective one of the at least two first p-type body regions; and two gate trenches located between two adjacent first p-type body regions, where a second p-type body region is disposed between the two gate trenches. A gate dielectric layer and a gate are disposed in a respective one of the two gate trenches.

This application is a 35 U.S.C. 371 national stage filing and claims priority to International Patent Application No. PCT/CN2019/120486, filed on Nov. 25, 2019 which claims priority to Chinese patent application No. 201910829144.0, filed with the CNIPA on Sep. 3, 2019, the disclosures of each of which is are incorporated herein by reference in their entireties.

### TECHNICAL FIELD

This application relates to the technical field of semiconductor power devices, in particular, a semiconductor power device with a super junction structure.

### BACKGROUND

FIG. 1 shows the cross-sectional structure of a semiconductor power device with a super junction structure in the related art, and the semiconductor power device with the super junction structure includes an n-type drain region 31 and an n-type epitaxial layer 30 upon the n-type drain region 31. The n-type drain region 31 is connected to a drain voltage through a drain metal layer 70. A gate trench is formed in the n-type epitaxial layer 30, and a gate dielectric layer 35 and a gate 36 are formed in the gate trench. The gate 36 controls turn-on and turn-off of the current channel through a gate voltage, where the current channel is located in a p-type body region 33. The p-type body region 33 and an n-type source region 34 are connected to a source voltage through a source metal layer 47. A p-type body contact region 38 with a high doping concentration is used to reduce ohmic contact. A p-type columnar epitaxial doped region 32 is formed under the p-type body region 33. An insulating dielectric layer 50 is an interlayer insulating layer.

Miller Capacitance (Crss) and gate-to-drain capacitance (Cgd) corresponding to the Miller Capacitance play an important role during turn-on and turn-off of the semiconductor power device with the super junction structure. The gate-to-drain capacitance of the semiconductor power device with the super junction structure in the related art is too small, which will cause a sudden change of the gate-to-drain capacitance during the turn-on and the turn-off of the semiconductor power device with the super junction structure, resulting in serious electromagnetic interference.

### SUMMARY

This application provides a semiconductor power device to solve the problem of serious electromagnetic interference caused by too small gate-to-drain capacitance of the semiconductor power device in the related art.

Provided is a semiconductor power device, including: an n-type drain region and an n-type epitaxial layer located upon the n-type drain region. The n-type epitaxial layer includes: at least two first p-type body regions, where an n-type source region is disposed in a respective one of the at least two first p-type body regions; a p-type columnar doped region located below the respective one of the at least two first p-type body regions; and two gate trenches located between two adjacent first p-type body regions, where a second p-type body region is disposed between the two gate trenches. A gate dielectric layer and a gate are disposed in a respective one of the two gate trenches.

In one embodiment, the second p-type body region is externally connected to a source voltage.

In one embodiment, a width of the second p-type body region is less than a width of each of the at least two first p-type body regions.

In one embodiment, the two gate trenches each include an upper part and a lower part. The gate and the gate dielectric layer are located in an upper part of the respective one of the two gate trenches, and a shield gate and a field oxide layer are disposed in a lower part of the respective one of the two gate trenches.

In one embodiment, the shield gate and the field oxide layer extend upward into the upper part of the respective one of the two gate trenches, and the shield gate is isolated from the gate by the field oxide layer.

In one embodiment, the shield gate is configured to divide the gate into a first gate facing toward the respective one of the at least two first p-type body regions and a second gate facing toward the second p-type body region.

In one embodiment, the first gate is externally connected to a gate voltage, and the second gate is externally connected to a source voltage.

The semiconductor power device provided by the application has a relatively large gate-to-drain capacitance, which can reduce electromagnetic interference caused by a sudden change of the gate-to-drain capacitance during turn-on and turn-off of the semiconductor power device.

### BRIEF DESCRIPTION OF DRAWINGS

FIG. 1 is a cross-sectional view of a semiconductor power device of the related art;

FIG. 2 is a cross-sectional view of a semiconductor power device according to the first embodiment provided by the application;

FIG. 3 is a cross-sectional view of a semiconductor power device according to the second embodiment provided by the application;

FIG. 4 is a cross-sectional view of a semiconductor power device according to the third embodiment provided by the application.

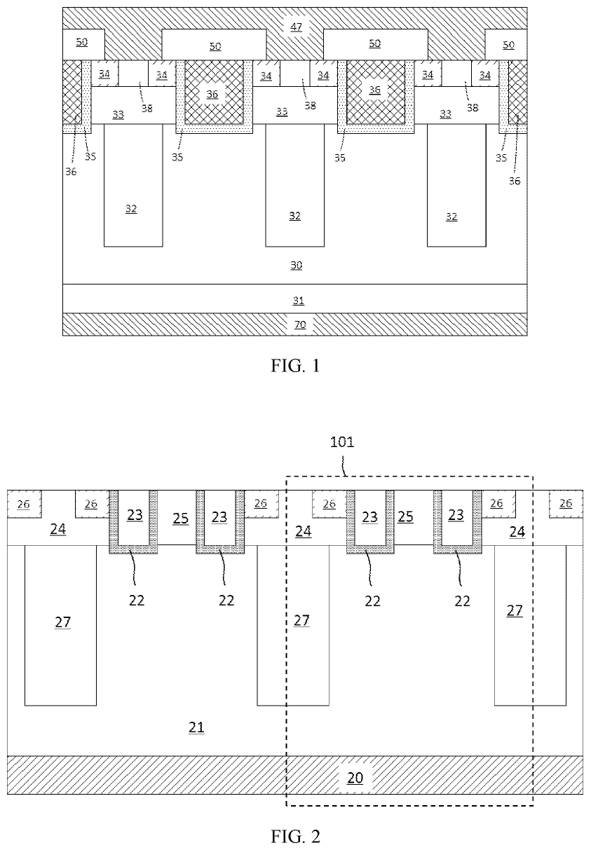

### DETAILED DESCRIPTION

The solutions of the application are to be completely described in specific ways with reference to the accompanying drawings in the embodiments of the application. Apparently, the embodiments described are a part (not all) of the embodiments of the application.

It should be noted that, the terms such as “having”, “comprising” and “including” used in this application do not equate the presence or addition of one or more other elements or their combinations thereof. At the same time, in order to clearly illustrate the specific implementation of the application, sizes in the figures listed in the drawings of the description do not represent the actual sizes, the drawings are exemplary and should not limit the scope of the application. The embodiments listed in the description should not be limited to the specific shapes shown in the drawings, they should include deviations of the resulting shapes caused by preparation.

FIG. 2 is a cross-sectional view of a semiconductor power device according to the first embodiment provided by the present application. As shown in FIG. 2, the semiconductor power device provided by the first embodiment of the present application includes an n-type drain region 20 and an n-type epitaxial layer 21 located on the n-type drain region 20. The n-type drain region 20 can be externally connected to a drain voltage through a drain metal layer. At least two first p-type body regions 24 and two gate trenches 29 located between two adjacent first p-type body regions 24 are located in the n-type epitaxial layer 21.

FIG. 2 exemplarily shows the structure of three first p-type body regions 24, and for the convenience of display and description, FIG. 2 exemplarily shows a minimum unit structure 101 of the present application.

An n-type source region 26 is disposed in the first p-type body region 24, and a p-type columnar doped region 27 is disposed below the first p-type body region 24. The p-type columnar doped region 27 may be connected or disconnected to the first p-type body region 24. As an example, the p-type columnar doped region 27 in FIG. 2 can be connected to the first p-type body region 24. The first p-type body region 24 and the n-type source region 26 can be externally connected to the source voltage through the source metal layer.

A second p-type body region 25 is disposed between the two gate trenches 29. In one embodiment, the width of the second p-type body region 25 is less than the width of the first p-type body region 24, so that the size of the chip of the semiconductor power device can be reduced, thus reducing the manufacturing cost of the semiconductor power device.

A gate dielectric layer 22 and a gate 23 are disposed in each gate trench 29. The gate 23 can be externally connected to a gate voltage through the gate metal layer, so that the gate 23 can control turn-on and turn-off of the current channel in the first p-type body region 24 by the gate voltage.

In the semiconductor power device according to the embodiments provided by the present application, the two gate trenches are disposed between the adjacent first p-type body regions to form two gate structures, which can increase the gate-to-drain capacitance of the semiconductor power device, and further reduce the electromagnetic interference caused by the sudden change of the gate-to-drain capacitance during the turn-on and turn-off of the semiconductor power device. The second p-type body region is disposed between the two gate trenches, which can reduce the electric field intensity at the bottom of the gate, so that the manufacturing process window of the semiconductor power device becomes larger and the manufacturing stability of the semiconductor power device can be improved. In one embodiment, the source voltage may be externally added to the second p-type body region, which can further reduce the electric field intensity at the bottom of the gate.

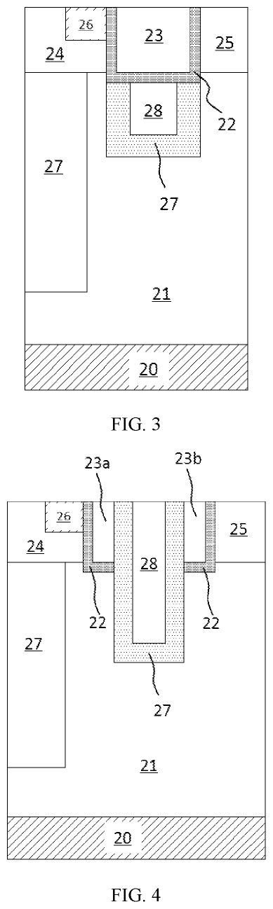

FIG. 3 is a cross-sectional view of a semiconductor power device according to the second embodiment provided by the present application. As shown in FIG. 3, the gate trench 29 of the semiconductor power device in the second embodiment of the present application includes an upper part 29a and a lower part 29b. The gate 23 and the gate dielectric layer 22 are located in the upper part 29a of the gate trench 29, and a shield gate 28 and a field oxide layer 27 are disposed in the lower part 29b of the gate trench 29. The shield gate 28 can be externally connected to the source voltage, so that electric field intensity at the lower part 29b of the gate trench 29 can be adjusted, thus the withstand voltage of the semiconductor power device can be improved.

FIG. 4 is a cross-sectional view of a semiconductor power device provided according to the third embodiment provided by the present application. As shown in FIG. 4, the semiconductor power device in the third embodiment of the present application are disposed on the basis of the semiconductor power device shown in FIG. 3, the shield gate 28 and the field oxide layer 27 extend upwardly into the upper part 29a of the gate trench 29, and the shield gate 28 is isolated from the gate by the field oxide layer 27. When the shield gate 28 and the field oxide layer 27 extend upwardly into the upper part 29a of the gate trench 29, the gate 23 can be divided into a first gate 23a facing toward the first p-type body region 24, and a second gate 23b facing toward the second p-type body region 25. The first gate 23a and the second gate 23b may be externally connected to the gate voltage at the same time; or that the first gate 23a is externally connected to the gate voltage, and the second gate 23b is externally connected to the source voltage.

What is claimed is:

1. A semiconductor power device, comprising: an n-type drain region and an n-type epitaxial layer located upon the n-type drain region,
wherein the n-type epitaxial layer comprises:
at least two first p-type body regions, wherein an n-type source region is disposed in a respective one of the at least two first p-type body regions;
a p-type columnar doped region located below the respective one of the at least two first p-type body regions; and
two gate trenches located between two adjacent first p-type body regions, wherein a second p-type body region is disposed between the two gate trenches;
wherein a gate dielectric layer and a gate are disposed in a respective one of the two gate trenches.

2. The semiconductor power device of claim 1, wherein the second p-type body region is externally connected to a source voltage.

3. The semiconductor power device of claim 1, wherein a width of the second p-type body region is less than a width of each of the at least two first p-type body regions.

4. The semiconductor power device of claim 1, wherein the two gate trenches each comprise an upper part and a lower part, the gate and the gate dielectric layer are located in the upper part of the respective one of the two gate trenches, and a shield gate and a field oxide layer are disposed in the lower part of the respective one of the two gate trenches.

5. The semiconductor power device of claim 4, wherein the shield gate and the field oxide layer extend upward into the upper part of the respective one of the two gate trenches, and the shield gate is isolated from the gate by the field oxide layer.

6. The semiconductor power device of claim 5, wherein the shield gate is configured to divide the gate into a first gate facing toward the respective one of the at least two first p-type body regions and a second gate facing toward the second p-type body region.

7. The semiconductor power device of claim 6, wherein the first gate is externally connected to a gate voltage, and the second gate is externally connected to a source voltage.
